(19) United States
(12) Patent Application Publication
(10) Pub. No.: US 2012/0103387 A1
(43) Pub. Date: May 3, 2012

(54) PHOTOVOLTAIC COMPONENT

(75) Inventors: Gerd FISCHER, Dohne OT Borthen (DE); Bernd BITNAR, Bannewitz (DE); Torsten WEBER, Dresden (DE); Matthias GEORGI, Dresden (DE)

(73) Assignee: SOLARWORLD INNOVATIONS GMBH, Freiberg (DE)

(21) Appl. No.: 13/282,326

(22) Filed: Oct. 26, 2011

(30) Foreign Application Priority Data
Oct. 27, 2010 (DE) 10 2010 043 006.4

(51) Int. Cl. H01L 31/05; H01L 51/48; H01L 31/06

(52) U.S. Cl. 136/244; 136/255; 438/64; 257/E51.012

(57) ABSTRACT

The present invention relates to a photovoltaic component comprising a superimposed arrangement of at least one inorganic solar cell and at least one organic solar cell. The inorganic solar cell comprises a translucent backside opposite to the organic solar cell. The present invention further relates to a method of producing a photovoltaic component.

### FIELD

The present invention relates to a photovoltaic component and to a method of producing a photovoltaic component.

### BACKGROUND

Solar cells are used to convert electromagnetic radiation energy (typically sunlight) into electrical energy. The energy conversion is based on radiation being subject to an absorption in a solar cell, thus generating positive and negative charge carriers (“electron-hole pairs”). The generated free charge carriers are furthermore separated from each other in order to be discharged via separate contacts. In a solar module, a plurality of solar cells operating according to this functional principle are generally combined.

Known solar cells are usually made of an inorganic semiconductor material, e.g. silicon, and comprise two regions having different conductivity or, respectively, doping. Between these two regions which are also referred to as “base” and “emitter”, a p-n junction is present. In this context, an internal electrical field occurs which causes the above-described separation of the charge carriers generated by radiation.

A key demand to solar cells is achieving as high an efficiency as possible or, respectively, as high a radiation yield as possible. In solar cells having a p-n junction, the efficiency factor is amongst other things limited by the Shockley-Queisser limit. This takes the excitation process of electrons in a semiconductor into account and refers to the fact that the energy extraction depends on the bandgap of the semiconductor in question. In other words, photons having an energy smaller than that of the bandgap do not contribute in the generation of photoelectric current.

Higher efficiency may be achieved by means of what is known as tandem solar cells which are composed of different semiconductor materials having differing bandgaps and which comprise a plurality of p-n junctions. In this regard, e.g. EP 1 187 223 A2 describes a solar cell in which a monocrystalline silicon wafer is enclosed by two layers of amorphous silicon. A further example is a combination of microcrystalline and amorphous silicon layers for thin-film modules, as disclosed e.g. in DE 40 25 311 A1 and U.S. 2008/0173350 A1. Such concepts for increasing efficiency, however, come along with complex and expensive manufacture.

Apart from solar cells made of inorganic semiconductor materials, solar cells are known which consist of organic hydrocarbon compounds or polymeric compounds, respectively. Such organic solar cells, also referred to as “plastic solar cells”, usually comprise what is known as donor-acceptor system in which the separation of the charge carriers generated by means of radiation absorption is based on the gradient of an electro-chemical potential. In this context, as well, it is a known procedure to configure tandem solar cells from organic photoactive layers. Potential examples for organic solar cells are described in EP 0 975 026 A2 and in WO 2006/092134 A1.

Although it is true that organic solar cells may be produced in a relatively inexpensive manner, they exhibit lower efficiency when compared to inorganic solar cells and moreover, their long-term stability is insufficient. This is due to a degradation or disintegration, respectively, of the used organic materials as a result of the influence of higher-energy radiation portions (ultra-violet radiation or blue-light radiation, respectively). In solar modules consisting of organic solar cells, optical filters are thus typically used (e.g. within a or in the shape of a covering glass, respectively). This measure, however, comes along with a decrease of efficiency.

### SUMMARY

Various aspects of the present invention provide an improved photovoltaic component and an improved method of producing a photovoltaic component.

One embodiment of the present invention provides a photovoltaic component comprising a superimposed arrangement of at least one inorganic solar cell and at least one organic solar cell. The inorganic solar cell comprises a translucent backside opposite to the organic solar cell.

Another embodiment of the present invention provides a method of producing a photovoltaic component. In the method, at least one inorganic solar cell comprising a translucent backside is provided. Furthermore, at least one organic solar cell is provided. The at least one inorganic solar cell is connected to the at least one organic solar cell in such a way that the at least one inorganic solar cell and the at least one organic solar cell are arranged on top of each other and the translucent backside of the inorganic solar cell is opposite to the organic solar cell.

### BRIEF DESCRIPTION OF THE DRAWINGS

These and other features of the present invention will become clear from the following description taken in conjunction with the accompanying drawings. It is to be noted, however, that the accompanying drawings illustrate only typical embodiments of the present invention and are, therefore not to be considered limiting of the scope of the invention. The present invention may admit other equally effective embodiments.

FIG. 1 shows a schematic lateral sectional view of a photovoltaic component comprising a superimposed arrangement of an inorganic and an organic solar cell;

FIGS. 2 to 4 are schematic views of solar modules comprising different electric interconnections of inorganic and organic solar cells;

FIG. 5 depicts a diagram for illustrating steps of a method for manufacturing a solar module; and

FIGS. 6 to 8 show in the form of tables individual manufacturing processes which may be carried out with respect to the method of FIG. 5.

### DETAILED DESCRIPTION

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

The present invention provides a photovoltaic component which comprises a superimposed arrangement of at least one inorganic solar cell and at least one organic solar cell. The inorganic solar cell comprises a translucent backside opposite to the organic solar cell.

The photovoltaic component, which may be a multiple solar cell or a photovoltaic or solar module, respectively, comprises a combination of at least one inorganic and at least one organic solar cell. Such a combination allows for a relatively high efficiency and may moreover be realized in a simple and cost-efficient manner. During operation of the photovoltaic component, a portion of a light radiation may be absorbed in the (at least one) inorganic solar cell and be converted into electrical energy or electrical current, respectively. A portion of the light radiation not absorbed by the inorganic solar cell(s) may reach the organic solar cell(s) via the translucent backside(s) opposite or, respectively, facing the organic solar cell(s), and be converted into electrical energy, as well, by the organic solar cell(s). In the context of such a functionality, the (at least one) inorganic solar cell may serve as optical filter for the (at least one) organic solar cell. As a result, a degradation of the (at least one) organic solar cell may be suppressed or prevented, respectively.

With respect to the inorganic solar cell of the photovoltaic component, different configurations may be considered. It is e.g. conceivable that the inorganic solar cell comprises crystalline silicon, amorphous silicon, cadmium-telluride or a copper-compound as a material.

When using silicon for the inorganic solar cell, it is provided according to a further embodiment that the inorganic solar cell is formed from a crystalline silicon wafer.

In a further embodiment, the organic solar cell comprises a smaller bandgap than the inorganic solar cell. In this manner, the organic solar cell may utilize a lower-energy portion of a light radiation, and the inorganic solar cell may utilize a higher-energy portion of the light radiation for generating electric energy. By means of this, a high efficiency of the photovoltaic component is possible and the inorganic solar cell may serve as an effective filter for protecting the organic solar cell.

In this context, it may e.g. be provided that the bandgap of the organic solar cell is smaller than 0.8 eV, or smaller than 0.7 eV. Such a bandgap, which is small compared to the bandgap of silicon amounting to 1.1 eV, may further favour achieving a high efficiency of the photovoltaic component.

In a further embodiment, the backside of the inorganic solar cell is passivated by means of a translucent dielectric. In this manner, a recombination of charge carriers in the inorganic solar cell may be reduced or suppressed, respectively, which may further favourably affect the efficiency of the photovoltaic component.

According to a further embodiment, recombination losses may also be reduced by the inorganic solar cell comprising a back-surface-field at its backside. Such a backside field which may be generated in the area of the backside by means of a corresponding doping of the inorganic solar cell has the effect of a mirror which may reflect generated charge carriers.

In a further embodiment, the photovoltaic component is a solar module comprising one or a plurality of inorganic solar cells having a translucent front- and backside as well as one or a plurality of organic solar cells. The inorganic solar cell or the plurality of inorganic solar cells is arranged in the area of a side of the solar module, which faces light radiation during operation. The organic solar cell or the organic solar cells are arranged in the area of a side of the solar module which faces away from the light radiation during operation of the solar module. Such a solar module may also provide the advantages of cost-efficient manufacturing, high efficiency and long lifetime.

In a configuration of the photovoltaic component as a solar module, the at least one organic solar cell may be integrated into the solar module in different ways. In this context, it is provided according to a possible embodiment that the solar module comprises a back panel. The organic solar cell or the organic solar cells are arranged on an inner side of the back panel, thus allowing for effectively irradiating the organic solar cell(s) through the inorganic solar cell(s).

In a further embodiment, the solar module comprises a backside film. The organic solar cell or the organic solar cells are arranged on an inner side of the backside film.

In a further embodiment, the solar module comprises a flexible substrate on which the organic solar cell or the organic solar cells are arranged. At this, the flexible substrate forms a backside of the solar module.

When irradiated by means of a light radiation, organic solar cells are typically only able to generate a weaker current than inorganic solar cells. In order to allow for effective current generation in spite of this differing behaviour, different interconnections are possible for the photovoltaic component.

In a possible embodiment, the photovoltaic component comprises a parallel connection of an arrangement of inorganic solar cells connected in series and of an arrangement of organic solar cells connected in series. In the separate series connections, the current generatable by means of the same type of solar cells may flow without a different type of solar cell being able to change or, respectively, reduce the total current. In the parallel connection, the currents achievable by the different solar cells add up, while the overall voltage remains the same. In order to make sure that the overall voltage in the parallel circuit is not changed or, respectively, reduced, it may further be provided that the arrangements of the inorganic and organic solar cells connected in series each deliver the same voltage. This may be achieved by providing adjusted numbers of inorganic and organic solar cells.

In a further embodiment by means of which the impact of different temperature dependencies of the voltage of organic and inorganic solar cells may be reduced or, respectively, prevented, the photovoltaic component comprises a series connection of an arrangement of inorganic solar cells connected in series and of an arrangement of organic solar cells. In order to avoid a reduction of the current flowing through the entire series circuit due to a lower current generation by the organic solar cells in this, the arrangement of organic solar cells comprises a plurality of series connections of organic solar cells connected in parallel. As a result, the arrangement of organic solar cells is able to generate the same amount of current as the arrangement of inorganic solar cells.

In a further embodiment, the photovoltaic component comprises an arrangement of inorganic solar cells, an arrangement of organic solar cells and one or a plurality of converter devices for adjusting voltage or current. At this, the converter devices may be used for adjusting the voltage or current, respectively, of the different cell types, e.g. by transforming the voltage of the solar cell arrangement of one cell type or that of both cell types.

In a further embodiment, the photovoltaic component is a multiple solar cell comprising an inorganic solar cell and one or a plurality of organic solar cells. The inorganic solar cell is formed from a crystalline silicon wafer and comprises a translucent front- and backside. The organic solar cell or the plurality of organic solar cells is arranged in the area of the backside of the inorganic solar cell. Such a multiple solar cell which may be manufactured inexpensively may exhibit high efficiency and high long-term stability.

The present invention furthermore provides a method of producing a photovoltaic component. The method comprises providing at least one inorganic solar cell comprising a translucent backside as well as providing at least one organic solar cell. Moreover, connecting the at least one inorganic solar cell with the at least one organic solar cell in such a way that the at least one inorganic solar cell and the at least one organic solar cell are arranged on top of each other and the translucent backside of the inorganic solar cell is opposite to the organic solar cell is provided. Such a method which may be carried out in a simple and cost-efficient manner allows for manufacturing of a photovoltaic component with a high efficiency and long life-time.

Further according to the invention, a backside film for a solar module is proposed which comprises one or a plurality of organic solar cells. Such a backside film may be produced inexpensively and be integrated in a solar module in a simple manner in order to increase the efficiency of the solar module.

The organic solar cell or the organic solar cells may be arranged on an inner side of the backside film, thus allowing for effective irradiation of the organic solar cell(s).

Further embodiments are explained in more detail in conjunction with the accompanying drawings.

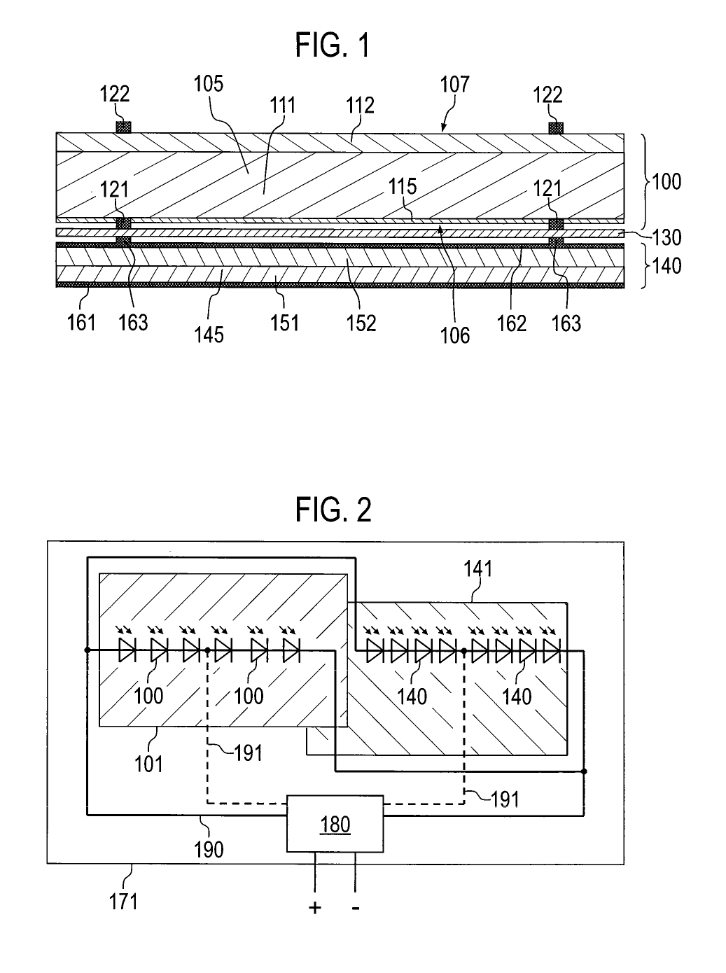

FIG. 1 shows a schematic lateral sectional view of a photovoltaic component comprising an inorganic solar cell 100 and an organic solar cell 140 which are arranged on top of each other or in the form of a stack, respectively. The depicted component may e.g. be a solar module or a section of a solar module, respectively. In this context, it is to be noted that apart from the depicted structures and elements, the photovoltaic component may comprise further elements which are not shown herein.

The inorganic solar cell 100 comprises a substrate 105 in which a frontside 107 as well as a backside 106 opposite to the frontside 107 is translucent to radiation or light, respectively, in a manner comparable to a bifacial solar cell. The inorganic solar cell 100 may be a silicon solar cell so that the substrate 105 may represent a crystalline silicon wafer or the inorganic solar cell 100 may be formed from such a silicon wafer, respectively.

The substrate 105 of the inorganic solar cell 100 comprises two substrate regions 111, 112 having different conductivity or doping, respectively, which may also be referred to as base 111 and emitter 112. In this context, e.g. the base 111 may comprise a p-doping and the emitter 112 may comprise an n-doping (p-type base 111, n-type emitter 112). A p-n junction exists between the base 111 and the emitter 112, the p-n junction generating an internal electrical field in the substrate 105. During operation of the photovoltaic component, a separation of free charge carriers which are generated by radiation absorption within the substrate 105 during irradiation of the inorganic solar cell 100 by means of light radiation may be effected in this manner. At this, the photovoltaic component or its inorganic solar cell 100, respectively, are arranged in such a way with regard to light radiation that the frontside 107 of the substrate 105 faces the light. A portion of the radiation not absorbed in the inorganic solar cell 100 may leave the inorganic solar cell 100 via the translucent backside 106 of the substrate 105 and reach further to the organic solar cell 140. This radiation may be low-energy light or long-wave light in an energy region below the bandgap of the substrate material (silicon).

The substrate backside 106 of the inorganic solar cell 100 is passivated by means of a translucent dielectric 115, as further depicted in FIG. 1. As a material for the dielectric 115, e.g. silicon oxide or silicon nitride may be considered. Such a dielectric backside passivation 115 allows for reducing or, respectively, suppressing a recombination of the charge carriers generated within the substrate 105 and thus associated yield losses. The translucency of the dielectric 115 particularly refers to the above-described long-wave portion of the light radiation which is not subject to absorption within the inorganic solar cell 100. The translucency may be realized by means of a corresponding (low) thickness of the dielectric 115.

As further depicted in FIG. 1, the inorganic solar cell 100 comprises a contact structure including contact elements 121 arranged at the backside 106 and contact elements 122 arranged at the frontside 107, by means of which the poles of the p-n junction (i.e. base 111 and emitter 112) may be contacted for current and energy generation. The contact elements 121, 122 which comprise an electrically conductive or, respectively, metallic material are each configured in the shape of (in a top view) thin fingers or in the shape of a contact grid, respectively, in order to achieve as low a shadowing or, respectively, covering effect as possible on the translucent front- and backside 107, 106 of the substrate 105. The backside contact elements 121 further extend through the dielectric 115 to the base 111 in order to be able to contact the base 111.

The organic solar cell 140 arranged below the inorganic solar cell 100, which faces the backside 106 of the inorganic solar cell 100, comprises a photoactive organic layer arrangement 145 of hydrocarbon compounds or polymeric compounds, respectively. The layer arrangement 145 is configured to provide a separation of the charge carriers generated by radiation absorption in a manner comparable to the p-n junction of the inorganic solar cell 100. As indicated in FIG. 1, the layer arrangement may be configured in the shape of a donor-acceptor system comprising an acceptor 151 and a donor 152 in which the charge separation is based on the gradient of an electro-chemical potential. The acceptor 151 and the donor 152 may e.g. be thin films of conjugated polymers and fullerenes. A possible example is a donor-acceptor system on the basis of copolymer thiophene and benzo-bis(thiadiazole):phenyl-C61-butyric acid methyl ester or Sn-phthalocyanine:C60.

The organic solar cell 140 or its photoactive layer arrangement 145, respectively, may comprise a smaller bandgap than the inorganic solar cell 100 or its substrate material (silicon), respectively. In this manner, the organic solar cell 140 may utilize the low-energy or, respectively, long-wave light radiation coming from the inorganic solar cell 100 (and not absorbed by the latter) for generating electric energy. It may be provided that the bandgap of the organic solar cell 140 is smaller than 0.8 eV, or even smaller than 0.7 eV. By means of such a bandgap, which is small compared to the bandgap of silicon amounting to 1.1 eV, a relatively large low-energy radiation portion (of the infrared wavelength range) may be converted into electric energy by the organic solar cell 140, which is associated with a high radiation yield.

This e.g. applies to the material example of a donor-acceptor system mentioned above for the organic solar cell 140.

Moreover, as depicted in FIG. 1, the organic solar cell 140 comprises a contact structure which is separate from the contact structure of the inorganic solar cell 100. The contact structure of the organic solar cell 140 comprises a full-area or, respectively, a large-area contact element 161 located at the backside and connected to the acceptor 151, as well as a full- or, respectively, large-area contact element 162 located at the frontside and connected to the donor 152, by means of which the photoactive layer arrangement 145 or, respectively, the acceptor 151 and the donor 152 may be contacted for current or energy generation, respectively. The large-area configuration of the contact elements 161, 162 is due to a relatively bad (compared to the inorganic solar cell 100) transverse conductivity of the organic solar cell 140 or of its photoactive layer arrangement 145, respectively.

For the frontside contact element 162, a transparent, electrically conductive material such as indium tin oxide (ITO) or aluminium-doped tin oxide (ZnO:Al) may be considered so that the organic solar cell 140 comprises a translucent frontside and the radiation coming from the backside 106 of the inorganic solar cell 100 may be coupled into the layer system 145 of the organic solar cell 140. As indicated in FIG. 1, further contact elements 163 in the shape of (in the top view) thin fingers or, respectively, in the shape of a contact grid may be arranged on the frontside contact element 162. Like the large-area contact element 162, the contact elements 163 may e.g. comprise indium tin oxide or, respectively, they may be manufactured together with the contact element 162 (by means of a corresponding structuring process), or they may comprise a different conductive or, respectively, metallic material. This material may also be nontransparent since due to the finger-shaped configuration, a shadowing effect on the frontside of the organic solar cell 140 may largely be avoided. The backside large-area contact element 161 of the organic solar cell 140, as well, may comprise any desired or, respectively, non-transparent electrically conductive or, respectively, metallic material.

Moreover, as is shown in FIG. 1, the two solar cells 100, 140 arranged on top of each other are mechanically connected by means of a layer or, respectively, a film made of an insulation 130. The insulation 130 comprises a transparent material so that the light radiation penetrating the inorganic solar cell 100 may (also) penetrate the insulation 130 or, respectively, reach the organic solar cell 140 (if possible) without any absorption. For this purpose, e.g. a translucent silicone material may be considered for the insulation 130. Contrary to the illustration in FIG. 1, the insulation 130 may completely fill out the intermediate region between the two solar cells 100, 140 so that no gaps or, respectively, air gaps occur between the solar cells 100, 140. Such an insulation 130 filling out the intermediate space may e.g. be configured within the framework of a lamination process.

The photovoltaic component of FIG. 1 may comprise a relatively high (total) efficiency due to the combination of inorganic and organic solar cells 100, 140. During operation of the photovoltaic component, the organic solar cell 100 or, respectively, its frontside 107 faces the light radiation (sun light) as already described above, wherein a higher-energy or, respectively, short-wave portion of the radiation, including UV radiation or, respectively, blue-light radiation, is absorbed in the inorganic solar cell 100 and converted into electric energy or, respectively, electric current. A low-energy or, respectively, long-wave portion of the light radiation, e.g. of the infrared wavelength range, which penetrates the inorganic solar cell 100 and is not absorbed by the inorganic solar cell 100, may leave the inorganic solar cell 100 via the translucent backside 106 opposite or, respectively, facing the organic solar cell 140, and reach further to the “downstream” organic solar cell 140 (through the transparent insulation 130). The organic solar cell 140, which is active in the low-energy or, respectively, infrared wavelength range may (further) convert the radiation coming from the inorganic solar cell 100 into electric energy.

In the case of such a functionality, the translucent inorganic solar cell 100 further acts as an effective optical filter for protecting the organic solar cell 140 since the higher-energy radiation portions which may cause a degradation or, respectively, a disintegration of the organic materials comprised by the organic solar cell 140 may (to a large extent) be absorbed in the inorganic solar cell 100. Due to this, the photovoltaic component may comprise a high long-term stability.

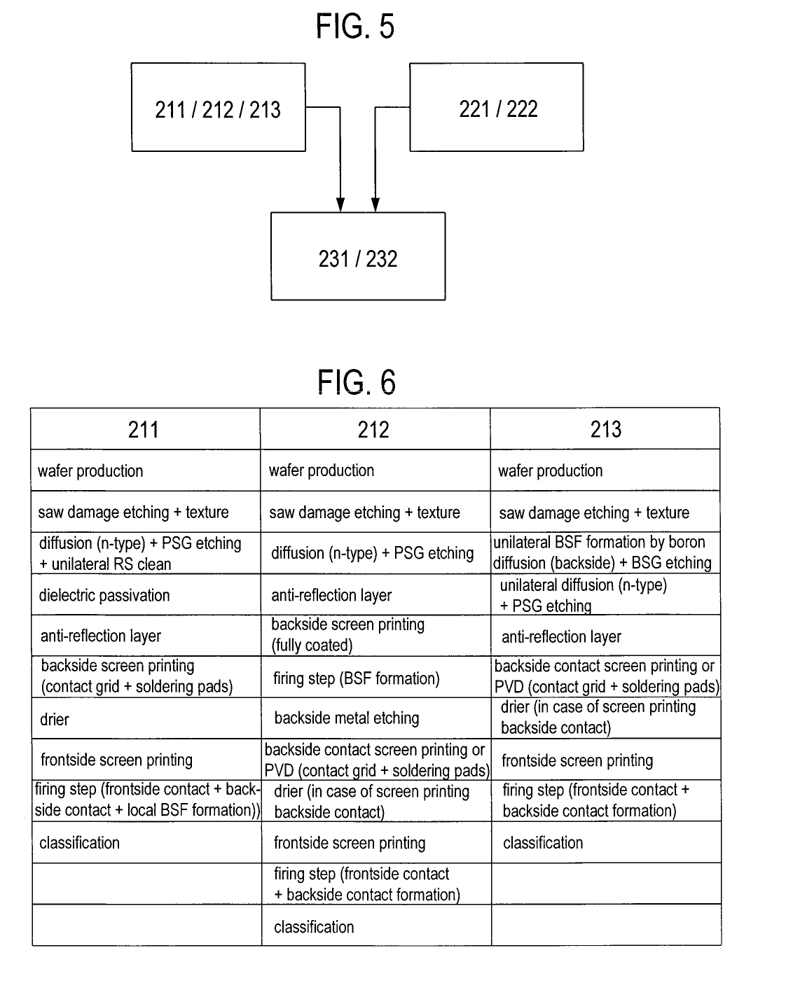

Apart from achieving a high efficiency and a high long-term stability, a further advantage is that the photovoltaic component or such a combination of inorganic and organic solar cells 100, 140, respectively, may be realized simply and inexpensively. This is true compared to known, complexly processed inorganic high-performance or, respectively, tandem solar cells. The inexpensive manufacture of the photovoltaic component may be based on the organic solar cell 140 or, respectively, its photoactive layer arrangement 145 being relatively inexpensive to produce. Possible manufacturing techniques will be discussed further below in more detail in conjunction with FIGS. 5 to 8.

The photovoltaic component of FIG. 1 may comprise further elements and structures (not depicted) apart from the depicted and described elements. For example, the frontside 107 of the inorganic solar cell 100 may be provided with a textured surface and/or may be coated with an anti-reflection layer. In this way, a reflection of light radiation at the frontside 107 of the inorganic solar cell 100 and yield losses associated therewith as a result may be reduced or, respectively, suppressed. In case the inorganic solar cell 100 is configured with an anti-reflection layer, the frontside contact elements 122 extend through the anti-reflection layer to the emitter 112 in order to be able to contact the emitter 112.

The inorganic solar cell 100 shown in FIG. 1 may further comprise a back-surface-field (BSF) at or, respectively, in the region of the backside 106 in addition or instead of the dielectric 115. Such a back-surface-field which may be generated by means of a corresponding doping of the base 111 in the region of the backside 106 (high p-doping or p⁺-doping in the case of a p-type base) has the effect of a mirror by means of which photoelectrically generated charge carriers (electrons) may be “reflected”. In this manner, as well, it is possible to reduce or, respectively, to suppress a recombination of charge carriers and losses associated therewith.

In a configuration of the photovoltaic component of FIG. 1 in the shape of a solar module, the component may comprise a plurality of inorganic solar cells 100 arranged side-by-side or, respectively, in the same plane instead of the merely one inorganic solar cell 100 shown, and/or a plurality of organic solar cells 140 arranged side-by-side or, respectively, in the same plane instead of the merely one organic solar cell 140 shown, wherein the solar cells 100, 140 are arranged on top of each other in the manner shown in conjunction with FIG. 1 and may be connected by means of a shared insulation 130.

In this context, the inorganic solar cells 100 are arranged in the region of a frontside facing the light radiation during operation of the solar module, and the organic solar cells 140 are arranged in the region of a backside of the solar module facing away from the light radiation during operation of the solar module. The organic solar cells 140 which in this configuration are opposite to, or, respectively, face the backsides 106 of the inorganic solar cells 100 may be irradiated through the inorganic solar cells 100 in the above-described manner.

The component configured as solar module may further e.g.

comprise a transparent glass pane at the frontside. With respect to the backside, it is e.g. possible that the solar module comprises a back panel (e.g. made of glass, as well), the organic solar cells 140 being arranged on an inner side of the back panel in order to allow for effective irradiation of the organic solar cells 140. It is alternatively possible that the solar module comprises a flexible substrate (e.g. made of plastic material) on which the organic solar cells 140 are arranged on an inner side. Here, the flexible substrate forms a backside of the solar module.

It is also possible to provide a backside film for the solar module, the backside film comprising one or a plurality of organic solar cells 140. As a material for the backside film, polyvinyl fluoride (PVF) which exhibits high weather resistance may e.g. be considered. The organic solar cell 140 or, respectively, the organic solar cells 140 may in this connection be arranged on an inner side of the backside film, thus allowing for an effective irradiation of the organic solar cell(s) 140 in the solar module. Such a backside film may be produced inexpensively and be integrated in the solar module in a simple manner in order to achieve an increase in efficiency or, respectively, in effectiveness of the solar module in question. In this regard, it is also conceivable to refit a conventional solar module with bifacial inorganic solar cells in order to increase effectiveness by means of such a backside film. A potential manufacture of a backside film provided with organic solar cells 140 is described further below in conjunction with FIG. 7 (process flow 222). An additional integration or refitting of a solar module may also be possible for the above-described back panel or for the above-described flexible substrate.

A further element to be considered for the photovoltaic component configured as a solar module is a frame. Moreover, the solar module may comprise an electrical contact device or, respectively, a connecting box to which the solar cells 100, 140 are connected by means of the contact elements 121, 122, 161, 162, 163 as well as by means of further connecting elements or connecting lines, respectively, which allows for (external) contacting of the solar module.

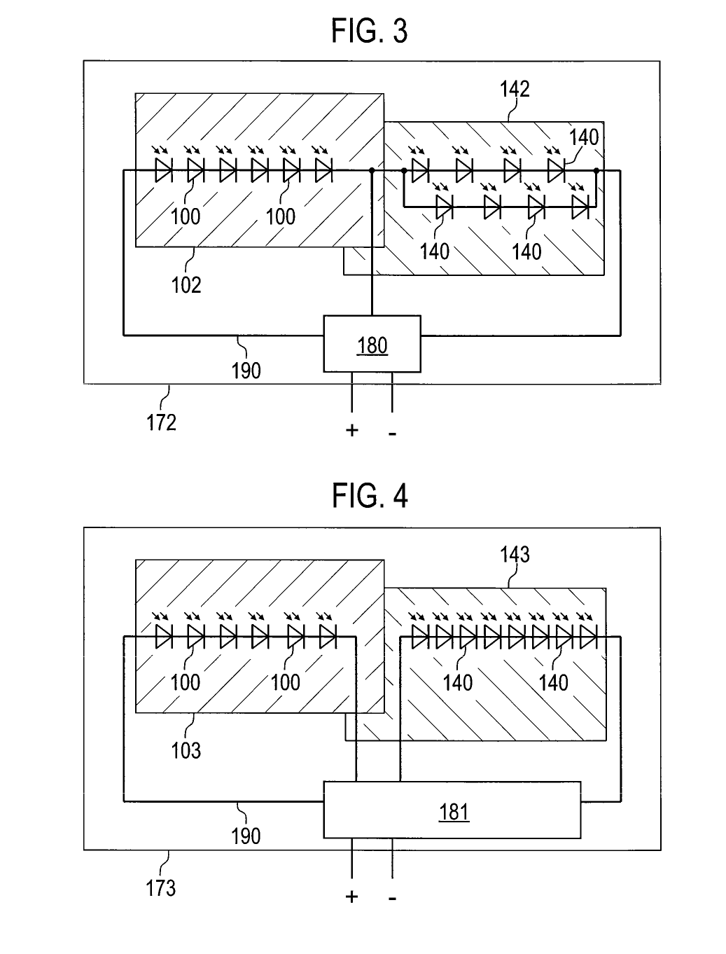

With respect thereto, solar modules 171, 172, 173 with possible interconnections of inorganic and organic solar cells 100, 140 will be described in more detail in the following in conjunction with FIGS. 2 to 4. The solar cells 100, 140 are in this context arranged on top of each other in a manner corresponding to FIG. 1 or in a comparable manner. It is hereby to be noted that reference is made to the above description with regard to already described details.

The interconnections depicted in FIGS. 2 to 4 allow for effective current generation by means of the solar cells 100, 140 in spite of a possibly differing current generating behaviour of the solar cells 100, 140. It is e.g. possible that organic solar cells 140 only generate a weaker current than inorganic solar cells 100 when irradiated with light radiation. A mere series connection of inorganic and organic solar cells 100, 140 would in this respect result in a reduction of the current flowing through the inorganic solar cells 100 or, respectively, of the current generatable by said inorganic solar cells 100. Such an impairment of functionality may be avoided by means of the interconnections of FIGS. 2 to 4.

FIG. 2 shows a schematic view of a solar module 171 comprising an arrangement 101 of inorganic solar cells 100 provided in the area of a frontside of the solar module 171 and an arrangement 141 of organic solar cells 140 provided in the area of a backside of the solar module 171. In the arrangement 101 as well as in the arrangement 141, the respective solar cells 100, 140 are each connected in series. The solar module 171 further comprises a connecting box 180 with externally contactable terminal elements which are labelled with “+” and “−”. The solar cell arrangements 101, 141 are connected to the connecting box 180 via electrical connection paths or, respectively, connecting lines 190.

As depicted in FIG. 2, the individual “strings” or, respectively, solar cell arrangements 101, 141 are connected to each other in a parallel connection and connected to the connecting box 180. In this manner, the current respectively generatable by the solar cells 100, 140 of the same type may flow in the separate series connections.

The total current of the parallel connection of the solar cell arrangements 101, 141 illustrated in FIG. 2 equals the sum of the individual currents flowing or, respectively, generated in the individual solar cell arrangements 101, 141. In order to achieve that the (total) voltage is not changed or, respectively, reduced in the parallel connection of the solar cell arrangements 101, 141 in which the same voltage occurs at each of the arrangements 101, 141, it is provided that the arrangements 101, 141 of the inorganic and organic solar cells 100, 140 connected in series each generate the same voltage. This may be achieved by providing adjusted numbers of inorganic and organic solar cells 100, 140 in the individual arrangements 101, 141.

Moreover, as is further indicated in FIG. 2 by means of dashed lines, the solar module 171 may comprise additional connecting lines 191 between the solar cells 100, 140 and the connecting box 180. These additional connecting lines 191 may e.g. be provided for bypass diodes (not shown) contained in the connecting box 180 by means of which an electric current may be routed past non-functional or not sufficiently functional, e.g. faulty or shaded solar cells 100, 140. The number of bypass diodes may be between one per module 171 or one per solar cell 100 or 140, respectively. In spite of connecting lines 191 only being indicated for the solar module 171 of FIG. 2, such a configuration may be provided for the solar modules 172, 173 of FIGS. 3 and 4, as well.

FIG. 3 shows a further schematic view of a solar module 172 comprising an arrangement 102 of inorganic solar cells 100 provided in the area of a frontside of the solar module 172 and an arrangement 142 of organic solar cells 140 provided in the area of a backside of the solar module 172, which are connected to a connecting box 180. In the arrangement 102, the inorganic solar cells 100 are connected in series. The arrangement 142, on the other hand, is a partial parallel connection of organic solar cells 142 in which a plurality of (e.g. two, as shown in FIG. 3) strings or, respectively, series connections of organic solar cells 140 are connected in parallel. The arrangement 142 of organic solar cells 140 is in this embodiment configured or, respectively, connected in such a way that the arrangement 142 generates the same amount of current as the arrangement 102 of inorganic solar cells 100. The total voltage of the two solar cell arrangements 102, 142 corresponds to a sum of the voltages generated by the individual solar cell arrangements 102, 142. It is thus possible to suppress an impact of differing temperature dependencies of the voltage of organic and inorganic solar cells 100, 140. The middle connection to the connecting box 180 serves to connect corresponding bypass diodes.

FIG. 4 shows a further schematic view of a solar module 173 comprising an arrangement 103 of inorganic solar cells 100 provided in the area of a frontside of the solar module 173 and an arrangement 143 of organic solar cells 140 provided in the area of a backside of the solar module 173. In the arrangement 103 as well as in the arrangement 143, the respective solar cells 100, 140 may each be connected in series, as depicted in FIG. 4.

The solar module 173 further comprises a connecting box 181 with one or a plurality of integrated DC converters (not shown), also referred to as “micro inverters”, to which the solar cell arrangements 103, 143 are connected separately from each other via associated connecting lines 190. In such a configuration, it is provided that the DC converter(s) of the connecting box 181 provide(s) a voltage or, respectively, current adjustment of the strings of both cell types, for this purpose e.g. transforming the voltage of one or of both solar cell arrangements 103, 143.

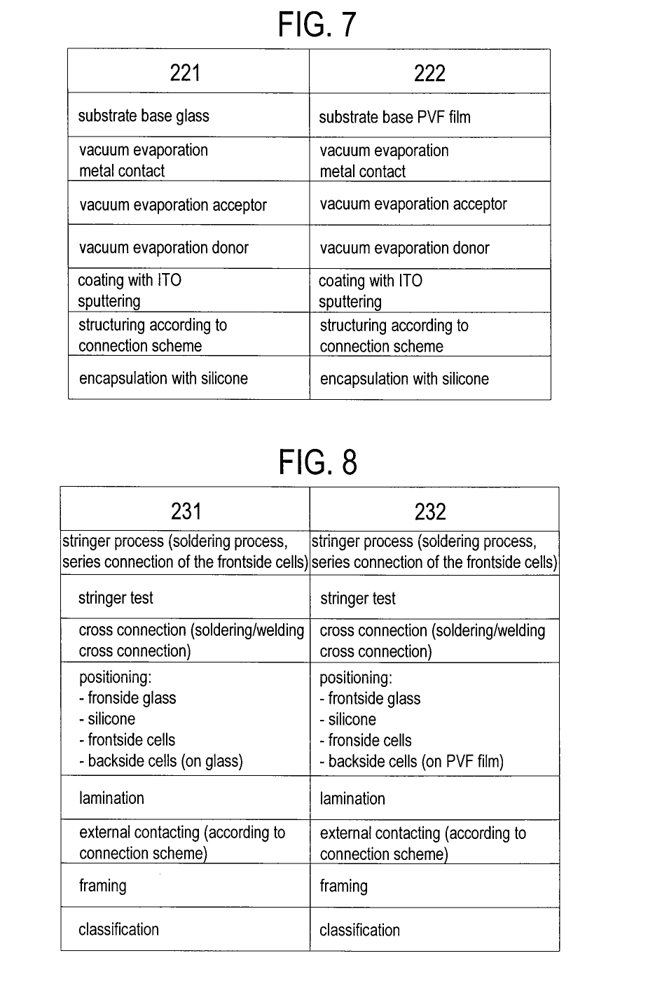

FIG. 5 shows a diagram for illustrating steps of a method for manufacturing a solar module comprising a superimposed arrangement of inorganic and organic solar cells 100, 140 corresponding to FIG. 1. In the method, inorganic solar cells 100 are provided according to a step or, respectively, process flow 211, 212 or 213. In a further step or, respectively process flow 221 or 222, an arrangement of organic solar cells 140 is provided. In a subsequent step or, respectively, process flow 231 or 232, these elements are assembled to form a solar module (“module configuration” or “module integration”, respectively). In the manufactured solar module, a connection of the solar cells 100, 140 e.g. according to a connection scheme as shown in FIGS. 2 to 4 may be provided. Furthermore, the inorganic solar cells 100 are arranged in a plane in the area of the frontside and the organic solar cells 140 are arranged in a plane in the area of the backside of the manufactured solar module. Thus, the inorganic solar cells 100 are in the following also referred to as “frontside cells”, whereas the organic solar cells 140 are referred to as “backside cells”. Individual processes of the aforementioned steps 211, 212, 213, 221, 222, 231, 232 of the method of FIG. 5, which will be explained in more detail in the following, are summarized in columns in the tables of FIGS. 6 to 8.

FIG. 6 shows different process flows 211, 212, 213 for manufacturing inorganic frontside cells 100 made of silicon. At the outset of process flow 211, wafers 105 are at first produced made of crystalline silicon, the wafers 105 comprising a p-conductive basic boron doping. The wafer production may comprise the steps of forming silicon blocks or rods (including doping) and sawing the same to obtain substrate discs or wafers 105, respectively. Saw damage occurring in this process is removed within the framework of an etching process. Within the framework of a further etching process, a (frontside) surface of the wafers 105 is provided with a structure referred to as texture, by means of which reflection losses during irradiation of the subsequent frontside cells 100 may be reduced.

Subsequently thereto, a diffusion process is carried out in order to introduce an n-doping into a narrow region in the area of the (frontside) surface of the p-conducting wafers 105 and to form an emitter-base structure (p-type base 111, n-type emitter 112) or, respectively, a p-n junction in the wafers 105 as a result thereof. This may be effected by processing the wafers 105 in a furnace having a phosphorus-containing ambient. A phosphorus silicate (PSG) formed on the surface of the wafers 105 during phosphorus diffusion is removed within the framework of a further etching process. In addition, the rear side or, respectively, the backside of the wafers 105 is subjected to a unilateral etching process for removing the backside emitter, as well as to a cleaning process by means of etching (“RS clean”).

Subsequently, a dielectric passivation 115 (e.g. made of silicon oxide or silicon nitride) is formed on the cleaned backside of the wafers 105, by means of which recombination losses in the subsequent frontside cells 100 may be reduced or suppressed, respectively. Moreover, an anti-reflection layer is formed on the frontside of the wafers 105 in order to achieve a (further) reduction of reflection losses. In this connection, e.g. silicon nitride may be deposited on the wafers 105 by means of plasma enhanced chemical vapour deposition (PECVD).

Afterwards, a screen printing process is carried out in which a contact structure or, respectively, a contact grid 121 made of an electrically conductive or, respectively, metallic paste (e.g. aluminium paste) including contact pads or, respectively, soldering pads is formed on the backside of the wafers 105. After a drying step for drying the paste in a drier, a further screen printing process is carried out in order to form a further contact grid 122 made of an electrically conductive or, respectively, metallic paste (e.g. aluminium or silver paste) including soldering pads on the frontside of the wafers 105. The order of the individual printing steps may be modified.

After that, a temperature or, respectively, sintering process follows which is referred to as a “firing step”. By means of said firing step, the frontside contact structure 122 is connected to the emitter 112 through the antireflection layer and the backside contact structure 121 is connected to the base through the dielectric backside passivation 115 (“fire-through process of the contacts”) and as a result, the formation of a frontside contact and of a backside contact is finalized. At the backside, a local back-surface-field is furthermore formed (by locally introducing e.g. aluminium atoms of the contact structure 121 into the base 111 of the wafers 105). After the firing step, the inorganic frontside cells 100 are completed. A classification is still carried out in which the frontside cells 100 are tested and classified according to optical and electrical features.

In the alternative process flow 212 of FIG. 6, the same initial processes as in process flow 211 are carried out, i.e. wafer production, saw damage etching and texture etching, followed by a diffusion process with phosphorus for producing an n-type emitter 112 at the frontside and an etching process for removing the PSG glass and the backside emitter formed thereby. Subsequently, an anti-reflection layer is formed on the frontside of the wafers 105 (such as e.g. silicon nitride by means of PECVD). Subsequently, a screen printing process is carried out in which the backside of the wafers 105 is fully coated with a metallic material (e.g. aluminium paste). Within the framework of a subsequent firing step, a part of the metallic material (aluminium atoms) is diffused into the backside of the wafers, thus forming a back-surface-field provided for reducing recombination losses. (Residual) metallic material located on the backside is furthermore subsequently removed in an etching process.

Subsequently, a screen printing process or a physical vapour deposition (PVD) is carried out in order to form an electrically conductive contact structure or, respectively, a contact grid 121 including soldering pads (comprising e.g. aluminium or silver) at the backside of the wafers 105. In the case of screen printing, an additional drying step is subsequently carried out in a drier. Thereupon, a (further) screen printing process (e.g. with aluminium or silver paste) is carried out in order to form a contact grid 122 and soldering pads at the frontside of the wafers 105.

In a subsequent firing step, the frontside contact structure 122 is connected to the emitter 112 (through the anti-reflection layer) and the backside contact structure 121 is connected to the base 111 of the wafers 105, and as a result, the formation of a frontside contact and of a backside contact is completed. The inorganic frontside cells 100 completed in this manner are finally subjected to a classification.

In the further alternative process flow 213 of FIG. 6, the same initial processes as in process flow 211 are again carried out, i.e. wafer production, saw damage etching and texture etching. Subsequently, a diffusion process with boron is carried out, during which boron is introduced into the backside of the wafers 105 and a back-surface-field provided for reducing recombination losses is formed. At this, in each case two wafers 105 may be arranged adjacently at the front sides (“back to back”) in order to effect merely unilateral diffusion.

This is followed by a (further unilateral) diffusion process with phosphorus in order to produce an n-type emitter 112 at the frontside of the wafers 105, as well as by an etching process for removing the PSG glass formed thereby. Subsequently, an anti-reflection layer is formed on the frontside of the wafers 105 (e.g. silicon nitride by means of PECVD).

Thereafter, a screen printing process or a PVD process is carried out in order to form an electrically conductive contact structure or, respectively, a contact grid 121 including soldering pads (comprising e.g. aluminium or silver) at the backside of the wafers 105. In case of a screen printing process, an additional drying process in a drier is moreover carried out subsequently. Thereupon, a (further) screen printing process (e.g. with aluminium or silver paste) is carried out in order to form a contact grid 122 as well as soldering pads at the frontside of the wafers 105.

In a subsequent firing step, the frontside contact structure 122 is connected to the emitter 112 (through the anti-reflection layer) and the backside contact structure 121 is connected to the base 111 of the wafers 105, and as a result, the formation of a frontside contact and of a backside contact is completed. The inorganic frontside cells 100 produced in this manner are finally subjected to classification. This process flow may also be transferred to solar cells comprising an n-doped base and a p-doped emitter. At this, the emitter is formed by means of the boron diffusion and the back-surface-field is formed by means of the phosphorus diffusion.

FIG. 7 shows different process flows 221, 222 for the manufacture of an arrangement of organic backside cells 140. At the beginning of the process flow 221, a substrate base made of glass or, respectively, a glass panel is at first provided which may serve as a back panel (or as a part of a back panel) of the subsequent solar module. On one side of the substrate base (inner side with regard to the solar module), full-area or, respectively, large-area metal contacts 161 are formed for the subsequent organic solar cells 140. Forming the metal contacts 161 is carried out within the framework of a vacuum evaporation. With regard to the structure of the metal contacts 161, the glass panel may in this connection be partly masked or a corresponding structuring method is carried out after the vacuum evaporation.

In the following, a vacuum evaporation for forming an acceptor layer 151 arranged on the metal contacts 161 and a vacuum evaporation for forming a donor layer 152 arranged on the acceptor layer 151 is carried out. The donor layer 152 is subsequently provided with an indium tin oxide coating (ITO) which is carried out within the framework of a sputtering process. The order of the deposition of the acceptor layer and of the donor layer may also be interchanged.

Subsequently, a process or, respectively, processes for structuring or, respectively, generating individual organic solar cells 140 from the previously deposited layer stack is/are carried out, the organic solar cells 140 being connected according to a predetermined connection scheme. In this respect, it is e.g. possible that at least the ITO layer is structured in order to form large-area contact elements 162 associated with the individual solar cells 140 and, if the case may be, to form finger-shaped contact elements 163 (cf. FIG. 1) arranged on the contact elements 162 and also formed from the ITO layer. The bad electrical transverse conductivity of the acceptor and donor layers 151, 152 in this context allows for the organic solar cells 140 to be furthermore (at least partly) connected via these layers 151, 152 and a “separation” being realized merely by means of the contact elements 161, 162. If applicable, a (partial) structuring of the acceptor layer 151 and additionally, if applicable, of the donor layer 152 may be carried out.

Within the framework of the above-described “structuring”, it may furthermore be provided as an alternative to form the finger-shaped contact elements 163 arranged on the contact elements 162 by means of a further coating process, and, if applicable, from a conductive or, respectively, metallic material different from ITO, such as e.g. ZnO:Al.

The process flow 221 finishes with a subsequent encapsulation or, respectively, lamination of the organic backside cells 140 arranged on the glass panel with a (transparent) silicone layer.

The alternative process flow 222 of FIG. 7 substantially corresponds to the above-described process flow 221. However, instead of a glass panel, a PVF film is used or, respectively, provided as a substrate base in this context. For the subsequent processes, reference is made to the above description of process flow 221.

FIG. 8 shows different process flows 231, 232 for assembling a solar module from the above-described elements. In this context, inorganic frontside cells 100 manufactured according to one of the process flows 211, 212, 213 may be used for both process flows 231, 232. The backside cells 140 manufactured according to process flow 221 and arranged on glass, on the other hand, are only used in process flow 231, and the backside cells 140 manufactured according to process flow 222 and arranged on the PVF film are only used in process flow 232.

At the outset of process flow 231, what is known as a stringer process is at first carried out in which the inorganic frontside cells 100 are connected in series by means of soldering and connected to form what is known as “strings”. Said strings are furthermore subjected to a test or, respectively, a stringer test. Subsequently, a plurality of frontside cell strings is connected to one another by means of soldering and/or welding via cross connections.

Subsequently, the inorganic and organic solar cells 100, 140 are positioned for a lamination process. In this context, a silicone layer is arranged on a provided glass panel (which forms the frontside of the solar module), an arrangement of transversely connected frontside cell strings is arranged thereon, and an arrangement of backside cells 140 formed on a glass panel (process flow 221) is arranged thereon. For the actual lamination, this arrangement is heated and pressed or, respectively, subjected to a overpressure, thus generating a rigid connection by means of the silicone, including the silicone used in the encapsulation of the organic solar cells 140. In the laminated composite manufactured in this manner, the frontside and backside cells 100, 140 arranged on top of each other (according to FIG. 1) are embedded in the isolating silicone between the frontside glass panel and the backside glass panel (on which the organic solar cells 140 have been generated according to process flow 221).

Subsequently, an external contacting in according with a predetermined connection scheme is carried out. In this context, installation of a connecting box 180, 181 or, respectively, an electrical connection with a connecting box 180, 181 of the solar module may be carried out. Furthermore, the composite produced by means of laminating is provided with a frame. The solar module completed in this manner is furthermore tested and classified according to optical and electrical features.

The alternative process flow 232 of FIG. 8 substantially corresponds to the above-described process flow 231. Instead of the backside cells 140 arranged on the (backside) glass panel, however, an arrangement of backside cells 140 arranged on a PVF film is used which has been manufactured according to process flow 222. As a result, the frontside and backside cells 100, 140 arranged on top of each other (according to FIG. 1) in the composite produced by means of lamination are embedded in the isolating silicone between the frontside glass panel and the PVF film (on which the organic solar cells 140 have been manufactured according to process flow 222). In this context, the PVF film may form a backside of the manufactured solar module. For further details, reference is made to the above description in conjunction with process flow 231.

The above-described combination or, respectively, superimposed arrangement of inorganic and organic solar cells 100, 140 is not only possible with respect to a solar module or, respectively, on a module level, but may alternatively be realized on the cell level, as well. In this regard, the photovoltaic component depicted in FIG. 1 may also be a multiple or, respectively stacked solar cell (or a section of such a multiple cell, respectively), which comprises a superimposed arrangement of an inorganic solar cell 100 and an organic solar cell 140. As described above, the inorganic solar cell 100 is in this context formed from a crystalline silicon wafer and comprises a translucent front- and backside 107, 106. The organic solar cell 140 is arranged in the area of the backside 106 of the inorganic solar cell 100 or, respectively, opposite to the backside 106, and connected to the inorganic solar cell 100 via the insulation 130. In this connection, the solar cells 100, 140 each comprise their own contact structures 121, 122 or 161, 162, 163, respectively.

Such a multiple solar cell may be manufactured inexpensively (as well) and exhibit a high efficiency as well as high long-term stability. For the manufacture of the multiple solar cell, it may be provided to configure the inorganic solar cell 100 according to a process flow 211, 212 or 213 of FIG. 6, to form the organic solar cell 140 on a PVF film or on a flexible substrate, wherein process steps may be carried out according to the process flows 211, 222 of FIG. 7, and to connect these elements to each other by laminating using a silicone insulation 130. Instead of only one organic solar cell 140, a multiple solar cell may also comprise a plurality of organic solar cells 140 arranged in the area of the backside 106 of the inorganic solar cell 100 or, respectively, facing the backside 106, the organic solar cells 140 being e.g. connected with each other in series or in parallel.

The embodiments described in conjunction with the Figures represent exemplary embodiments of the invention. Apart from the described and depicted embodiments, further embodiments are conceivable which may comprise further modifications or, respectively, combinations of features.

It is e.g. possible to realize a photovoltaic component comprising other materials than those described above. It is e.g. conceivable to configure an inorganic solar cell 100 made of amorphous silicon, cadmium-telluride, or a copper-compound. In this regard, the inorganic solar cell 100 may also be a thin-film solar cell instead of forming the inorganic solar cell 100 from a wafer. Furthermore, an inorganic solar cell 100 may be realized with different doping. Moreover, the base 111 and the emitter 112 of an inorganic solar cell 100 may be configured with inverted conductivities, i.e. an n-type base 111 and a p-type emitter. The use of alternative materials is also conceivable for a photoactive organic component or, respectively for an organic solar cell 140, for an insulation 130, for contact structures 121, 122, 161, 162, 163 etc.

In particular if other materials are used, manufacture of a photovoltaic component or solar module, respectively, may be effected in a different way instead of the above-described manufacturing process.

A further alternative consists in configuring a multiple solar cell comprising a stack arrangement of an inorganic solar cell 100 and one or a plurality of organic solar cells 140 in such a way that the inorganic solar cell 100 is directly connected to the organic solar cell 140 or, respectively, to the organic solar cells 140 (via the transparent backside 106). Such a monolithic configuration of the multiple solar cell is conceivable in case that the organic solar cell(s) 140 and the inorganic solar cell 100 may substantially produce the same current during irradiation.

Alternative embodiments are also conceivable for a backside film comprising one or a plurality of organic solar cells 140, which may be produced inexpensively and which may be assembled with inorganic solar cells 100 by means of known module manufacturing steps.

Instead of carrying out an interconnection of inorganic and organic solar cells 100, 140 on the module level in accordance with FIGS. 2 to 4, such an interconnection of solar cells 100, 140 may also be realized on a systemic level or, respectively, on the level of a photovoltaic plant which comprises a plurality of solar modules.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

1. A photovoltaic component comprising a superimposed arrangement of at least one inorganic solar cell and at least one organic solar cell,
wherein the inorganic solar cell comprises a translucent backside opposite to the organic solar cell,
and wherein the inorganic solar cell is formed from a crystalline silicon wafer.

2. The photovoltaic component according to claim 1, wherein the organic solar cell comprises a smaller bandgap than the inorganic solar cell.

3. The photovoltaic component according to claim 1, wherein the bandgap of the organic solar cell is smaller than 0.8 eV or smaller than 0.7 eV.

4. The photovoltaic component according to claim 1, wherein the backside of the inorganic solar cell is passivated by means of a translucent dielectric.

5. The photovoltaic component according to claim 1, wherein the inorganic solar cell comprises a back-surface-field at the backside.

6. The photovoltaic component according to claim 1, wherein the photovoltaic component is a solar module comprising one or a plurality of inorganic solar cells having a translucent front- and backside and one or a plurality of organic solar cells,
wherein the inorganic solar cell or the inorganic solar cells are formed from a crystalline silicon wafer,
wherein the inorganic solar cell or the inorganic solar cells are arranged in the area of a side of the solar module facing a light radiation during operation of the solar module,
and wherein the organic solar cell or the organic solar cells are arranged in the area of a side of the solar module facing away from the light radiation during operation of the solar module.

7. The photovoltaic component according to claim 6, comprising a back panel, the organic solar cell or the organic solar cells being arranged on an inner side of the back panel.

8. The photovoltaic component according to claim 6, comprising a backside film, the organic solar cell or the organic solar cells being arranged on an inner side of the backside film.

9. The photovoltaic component according to claim 6, comprising a flexible substrate on which the organic solar cell or the organic solar cells are arranged, the flexible substrate forming a backside of the solar module.

10. The photovoltaic component according to claim 1, comprising a parallel connection of an arrangement of inorganic solar cells connected in series and of an arrangement of organic solar cells connected in series.

11. The photovoltaic component according to claim 1, comprising a series connection of an arrangement of inorganic solar cells connected in series and of an arrangement of organic solar cells,
the arrangement of organic solar cells comprising a plurality of series connections of organic solar cells connected in parallel.

12. The photovoltaic component according to claim 1, comprising an arrangement of inorganic solar cells, an arrangement of organic solar cells and one or a plurality of converter devices for adjusting voltage or current.

13. The photovoltaic component according to claim 1, wherein the photovoltaic component is a multiple solar cell comprising an inorganic solar cell and one or a plurality of organic solar cells,
wherein the inorganic solar cell is formed from a crystalline silicon wafer and comprises a translucent front- and backside,
and wherein the organic solar cell or the plurality of organic solar cells is arranged in the area of the backside of the inorganic solar cell.

14. A method of producing a photovoltaic component comprising the steps of:
providing at least one inorganic solar cell comprising a translucent backside, wherein the inorganic solar cell is formed from a crystalline silicon wafer,
providing at least one organic solar cell, and
connecting the at least one inorganic solar cell to the at least one organic solar cell in such a way that the at least one inorganic solar cell and the at least one organic solar cell are arranged on top of each other and the translucent backside of the inorganic solar cell is opposite to the organic solar cell.

15. A photovoltaic component comprising a superimposed arrangement of at least one inorganic solar cell and at least one organic solar cell,
wherein the inorganic solar cell comprises a translucent backside opposite to the organic solar cell.

16. The photovoltaic component according to claim 15, wherein the inorganic solar cell comprises one of the following materials:
crystalline silicon, amorphous silicon, cadmium-telluride, or a copper-compound.
